(19) United States
(12) Patent Application Publication
(10) Pub. No.: US 2022/0045274 A1
(43) Pub. Date: Feb. 10, 2022

(54) OFETS HAVING ORGANIC SEMICONDUCTOR LAYER WITH HIGH CARRIER MOBILITY AND IN SITU ISOLATION

(71) Applicant: Facebook Technologies LLC, Menlo Park, CA (US)

(72) Inventors: Tingling Rao, Bellevue, WA (US); Lafe Purvis, Redmond, WA (US); Tanya Malhotra, Redmond, WA (US); Andrew John Ouderkirk, Kirkland, WA (US)

(21) Appl. No.: 17/098,492

(22) Filed: Nov. 16, 2020

Related U.S. Application Data
(60) Provisional application No. 63/061,972, filed on Aug. 6, 2020.

(51) Int. Cl. H01L 51/00; H01L 51/05

(52) U.S. Cl. CPC H01L 51/0012; H01L 51/0558

(57) ABSTRACT

An organic field effect transistor includes a channel structure defining an active area located between a source and a drain. The channel structure includes a photoalignment layer and an organic semiconductor layer disposed directly over the photoalignment layer. The photoalignment layer is configured to influence an orientation of molecules within the organic semiconductor layer and hence impact the mobility of charge carriers both within the active area and adjacent to the active area.

### CROSS-REFERENCE TO RELATED APPLICATION

This application claims the benefit of priority under 35 U.S.C. § 119(e) of U.S. Provisional Application No. 63/061,972, filed Aug. 6, 2020, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a cross-sectional schematic illustration of an organic field effect transistor having a templated organic semiconductor layer and a raised gate according to some embodiments.

FIG. 2 is a cross-sectional schematic illustration of an organic field effect transistor having a templated organic semiconductor layer and a buried gate according to some embodiments.

FIG. 3 is a cross-sectional schematic illustration of a pair of organic field effect transistors each having a templated organic semiconductor layer and a raised gate and separated by an isolation region according to some embodiments.

FIGS. 4-14 depict example crystallizable molecules that may be incorporated into an organic semiconductor layer according to certain embodiments.

FIG. 15 is an illustration of exemplary augmented-reality glasses that may be used in connection with embodiments of this disclosure.

FIG. 16 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

The present disclosure is generally directed to organic semiconductor materials, and more particularly to the molecular engineering of organic semiconductor thin films for implementation in organic field effect transistors (OFETs), organic light emitting diodes (OLEDs), organic photovoltaic devices, etc.

In various device architectures, an organic semiconductor layer may be disposed between conductive electrodes, which may include the source and drain of an exemplary logic device. The organic semiconductor layer may be semi-crystalline or a single crystal. The mobility of charge carriers and hence the electrical conductivity within the organic semiconductor layer may be related to the crystallinity and crystalline orientation of the organic semiconductor.

Notwithstanding recent developments, it would be advantageous to provide manufacturing methods and related architectures that enable the formation of organic semiconductor layers and associated devices having a repeatable and reliable alignment of crystal molecules that provide enhanced charge carrier mobility along a pre-designed direction, i.e., along a direction between the source and the drain.

In accordance with various embodiments, an organic semiconductor layer may be formed directly over a photoalignment layer. The photoalignment layer may be used as a templating layer to align crystallites within the organic semiconductor layer during its formation.

According to further embodiments, a photoalignment layer may be used to template the formation of an organic semiconductor having a low charge carrier mobility. That is, the photoalignment layer may be used also as a templating layer to misalign crystallites within the organic semiconductor layer during its formation.

Localized processing of the photoalignment layer may be used to create an organic semiconductor layer having both conductive and insulating properties. An organic semiconductor layer having a high charge carrier mobility region may be implemented, for example, within a channel structure between a source and a drain, whereas a region of low charge carrier mobility may be implemented within an isolation region, e.g., located adjacent to the channel structure. An isolation region may be configured to mitigate leakage current paths and/or suppress crosstalk between neighboring devices.

Transport in organic semiconductors refers to how charge carriers move through a material under the application of an electric field. For instance, transport can refer to the migration of excitons along or between polymer chains and/or crystals and may involve the process of energy transfer from one chain and/or crystal to another.

As will be appreciated, the function and performance of an organic device is typically related to the mobility of charge carriers. In an OLED, for example, the emission of photons may depend on the creation of an electric current within the device, which may be correlated to the motion of charge carriers to and from electrodes. Charge carrier mobility in transistors, on the other hand, may determine how fast the device can be switched on and off.

Charge carrier mobility is the speed (cm/s) at which charge carriers move in a material along a given direction under an applied electric field (V/cm).

As will be appreciated, charge carrier mobility may be increased by increasing the electronic coupling between adjacent units, i.e., molecules, polymer segments, or crystals. Charge carrier mobility within an organic semiconductor may depend on the structure or morphology of the material.

Organic semiconductor materials having planar n-conjugated cores generally show efficient charge transport along the n-n stacking direction. Organic molecules may aggregate according to intermolecular interactions and may tend to exhibit an edge-on molecular orientation on common substrates. With an edge-on orientation, molecular planes may be parallel to the substrate surface, which may be along the desired direction of current flow. Thus, an edge-on orientation may be suitable for in-plane charge transport in organic field effect transistors (OFETs), resulting in high charge carrier mobility. A face-on molecular orientation, on the other hand, with molecular planes oriented orthogonal to the substrate, may be beneficial for out-of-plane charge transport, where charges flow perpendicular to the substrate.

Template layering techniques may be used to control the molecular orientation of organic semiconductor layers, e.g., from edge-on to face-on or vice versa, as well as intermediate orientations, without changing the molecular structure, and thus impact the mobility of charge carriers along a particular direction, e.g., between the source and drain of an OFET.

A templating layer may include a photoalignment layer and an organic semiconductor layer may be formed directly over the photoalignment layer after exposing the photoalignment layer to polarized light. Exposure to polarized light can establish the orientation of the photoalignment layer and hence the orientation of the over-formed organic semiconductor.

In accordance with various embodiments, an organic semiconductor layer may include one or a combination of polycyclic aromatic hydrocarbons, such as naphthalene, anthracene, tetracene, pentacene, pyrene, polycene, fluoranthene, benzophenone, benzochromene, benzil, benzimidazole, benzene, hexachlorobenzene, nitropyridine-N-oxide, benzene-1, 4-dicarboxylic acid, diphenylacetylene, N-(4-nitrophenyl)-(s)-prolinal, 4,5-dicyanoimidazole, benzodithiophene, cyanopyridine, thienothiophene, stilbene, azobenzene, and derivatives thereof.

In some embodiments, an organic semiconductor layer may include one or a combination of ring-structured materials, including ring-structured molecules such as cyclohexane, cyclopentane, tetrahydropyran, piperidine, tetrahydrofuran, pyrrolidine, tetrahydrothiophene, and their derivatives. Further example ring-structured materials include thiophene, bi-phenyl, tolane, benzimidazole, diphenylacetylene, cyanopyridine, dibenzothiophene, carbazole, silafluorene, and derivatives thereof. As disclosed further herein, any of the presently-disclosed molecules may include one or more terminal groups, such as C1-C10 alkyl, alkoxy, or alkenyl groups, —CN, —NCS, —SCN, —SF₅, —Br, —Cl, —F, —OCF₃, —CF₃, and mono- or polyfluorinated C1-C10 alkyl or alkoxy group.

Still further organic semiconductor materials may include crystalline polymers having aromatic hydrocarbon or heteroarene groups and their derivatives. Example include polyethylene naphthalate, poly (vinyl phenyl sulfide), poly(a-methylstyrene, polythienothiophene, polythiophene, poly(n-vinylphtalimide), parylene, polysulfide, polysulfone, poly(bromophenyl), poly(vinylnaphthalene), and liquid crystal polymers having one or more functional groups as disclosed herein.

Organic semiconductor materials may include amorphous polymers having aliphatic, heteroaliphatic, aromatic hydrocarbon or heteroarene groups (e.g., polystyrene), and may include a binder and/or further additives such as fatty acid, sugars, lipids, plasticizers, and surfactants (e.g., molecules with mono- or polyfluorinated alkyl or alkoxy groups).

Photoalignment is a technique for orienting selected materials to a desired alignment by exposure to polarized light. Photo-aligning materials may contain photosensitive species with angularly dependent absorption. In liquid crystal (LC) systems, for example, molecules may exhibit substantial re-orientational autonomy, and photoreactions may trigger changes in the packing state or the collective molecular alignment.

Example photoalignment compositions may include azo-compounds, polyimides, polysilanes, polystyrenes, polyesters, cinnamates, coumarins, chalconyls, tetrahydrophthalimides, and maleimides.

The one or more organic semiconductor layers and the one or more photoalignment layers may be formed using a variety of methods as will be appreciated by those skilled in the art, such as solvent-based methods including ink-jet printing, blade coating, spin coating, dip coating, etc. The organic semiconductor layer(s) and the photoalignment layer(s) may be formed using the same method or using different methods. Further example methods include physical vapor transport processes. A zone-annealing step may be implemented to decrease the population of crystalline defects, which may improve charge carrier mobility. In accordance with some embodiments, an organic semiconductor layer and a photoalignment layer may form a channel structure of an organic field effect transistor.

Features from any of the embodiments described herein may be used in combination with one another in accordance with the general principles described herein. These and other embodiments, features, and advantages will be more fully understood upon reading the following detailed description in conjunction with the accompanying drawings and claims.

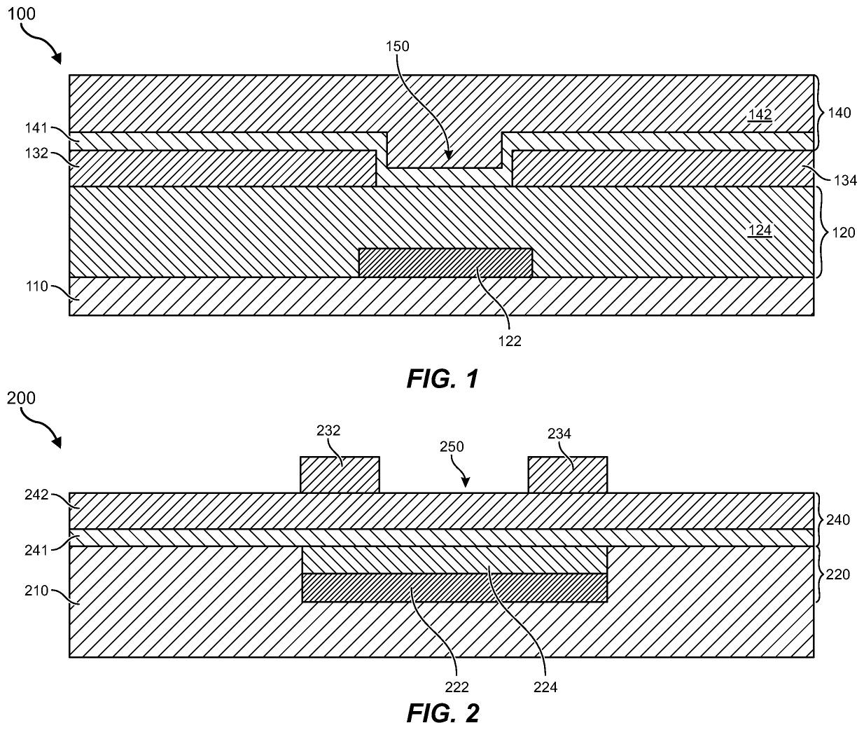

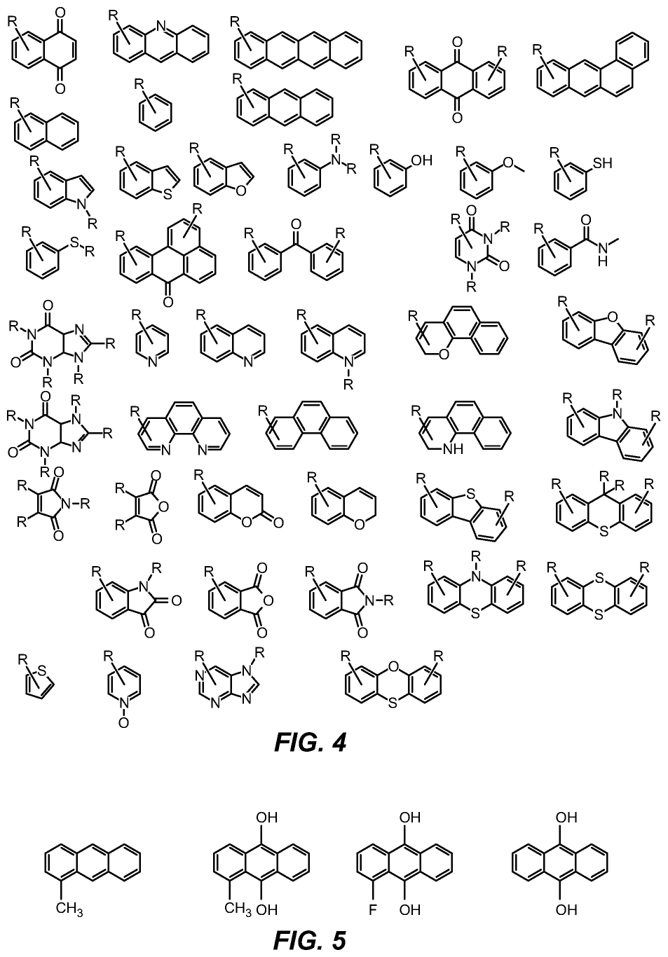

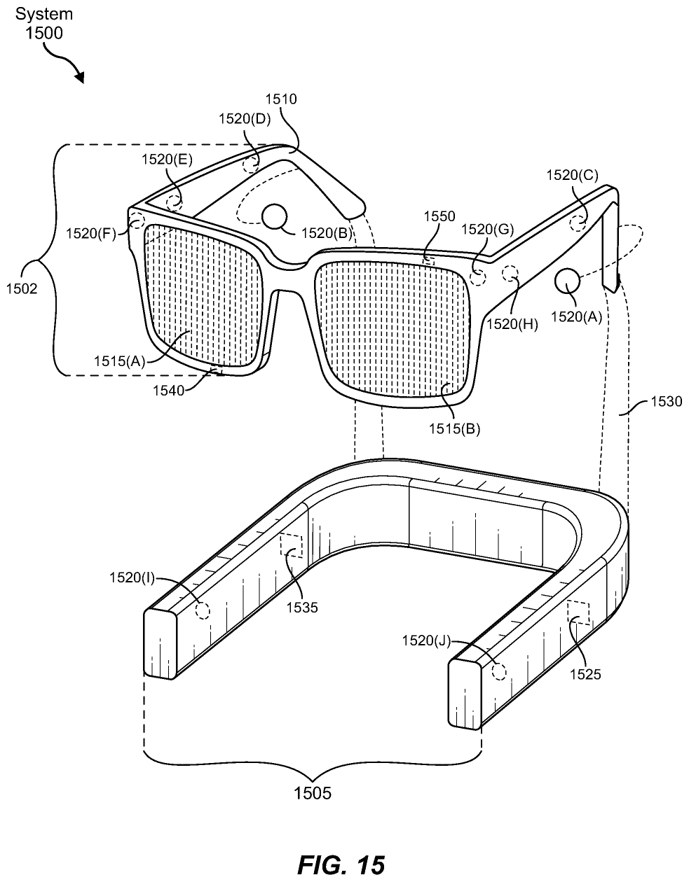

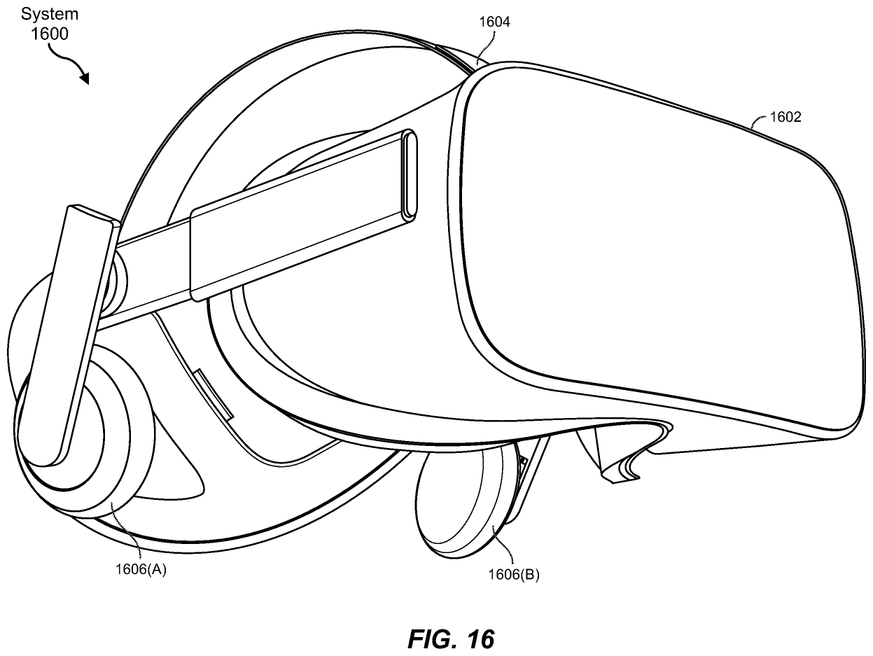

The following will provide, with reference to FIGS. 1-16, detailed descriptions of organic field effect transistors having a channel structure that includes an organic semiconductor layer templated by a photoalignment layer. The discussion associated with FIGS. 1-3 includes a description of example OFET architectures. The discussion associated with FIGS. 4-14 includes a description of various materials that may be incorporated into the organic semiconductor layer. The discussion associated with FIGS. 15 and 16 relates to various virtual reality platforms that may include a display device as described herein.

Referring to FIG. 1, illustrated is a cross-sectional view of an example OFET. OFET 100 may be used in a variety of applications, including integrated circuits, displays, biosensors, and memory devices. The OFET 100 includes a substrate 110. Substrate 110 may include a semiconductor such as silicon (Si) or gallium arsenide (GaAs), although other materials may be used, including plastics and polymers such as polyester, polyimide, or polyamide.

A gate structure 120 overlies substrate 110. The gate structure 120 may include a gate 122 and a gate dielectric 124 overlying the gate. The gate 122 may include any suitable conductive material, such as silver, platinum, or gold, or a conductive polymer. The gate dielectric 124 may include silicon dioxide or aluminum oxide, for example.

OFET 100, which may be a bottom contact OFET, also includes a source 132 and a drain 134 overlying the gate dielectric 124 and spaced apart to define an active area 150. A channel structure 140 extends through the active area 150 and includes a photoalignment layer 141 and an organic semiconductor layer 142 disposed directly over the photoalignment layer 141. Gate 122 may be located proximate to active area 150. In the OFET of FIG. 1, the channel structure 140 may be deposited after the source and drain electrodes 132, 134, which may lessen the propensity for degradation of the organic semiconductor layer 142 during its formation.

Referring to FIG. 2, illustrated is a cross-sectional view of a further example OFET. The OFET 200, which may be a top contact OFET, includes a substrate 210 and a gate structure 220 embedded within the substrate 210. Gate structure 220 may include a gate 222 and a gate dielectric 224 overlying the gate 222.

Overlying the embedded gate structure 220, OFET 200 may include a channel structure 240. Channel structure 240 includes a photoalignment layer 241 and an organic semiconductor layer 242 disposed directly over the photoalignment layer 241. A source 232 and a drain 234 are disposed over the organic semiconductor layer 242 and spaced apart to define an active area 250. In the top contact OFET of FIG. 2, at least a portion of the organic semiconductor layer 242 is disposed between the substrate 210 and the source and drain 232, 234.

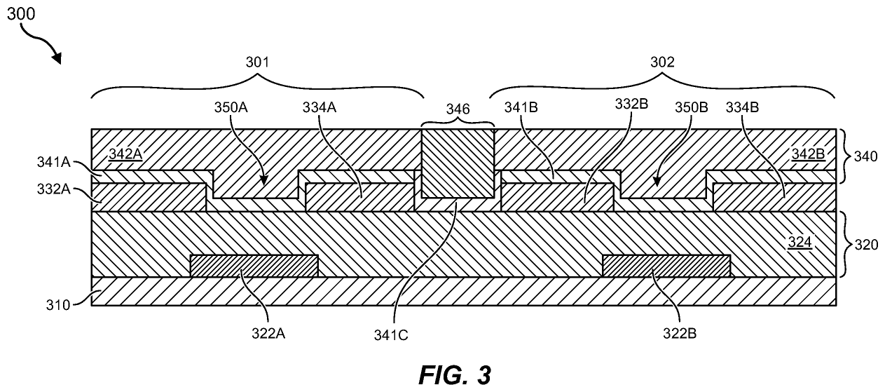

Turning to FIG. 3, an OFET 300 may include a first device 301 and an adjacent second device 302. First device 301 and second device 302 may share a common substrate 310. A gate structure 320 disposed over the substrate 310 may include a first gate 322A, a second gate 322B and a gate dielectric 324 overlying each of the first gate 322A and the second gate 322B.

First device 301 may include a first source 332A and a first drain 334A overlying the gate dielectric 324 and spaced apart to define a first active area 350A, whereas second device 302 may include a second source 332B and a second drain 334B overlying the gate dielectric 324 and spaced apart to define a second active area 350B.

A channel structure 340 includes a photoalignment layer 341A, 341B associated with first and second devices 301, 302 and a layer of an organic semiconductor 342A, 342B disposed directly over the photoalignment layer 341A, 341B. Each gate 322A, 322B may be located proximate to a respective active area 350A, 350B.

Illumination of the photoalignment layer 341A, 341B with polarized light may be used to induce a desired orientation of molecules and accordingly a desired charge carrier mobility within organic semiconductor layer 342A, 342B independently for each device 301, 302, i.e., within active areas 350A, 350B. Furthermore, illumination of the photoalignment layer 341C with different polarize light may be used to form an isolation region 346 within the organic semiconductor layer between devices 301, 302.

Example molecules that may be used to form the organic semiconductor layer are shown in FIGS. 4-13. The illustrated materials may be used as enantiomerically pure compositions or as racemic mixtures and may be used alone or in any combination. In the illustrated structures, “R” may include any suitable functional group, including but not limited to, CH₃, H, OH, OMe, OEt, OiPr, F, Cl, Br, I, Ph, NO₂, SO₃, SO₂Me, i-Pr, Pr, t-Bu, sec-Bu, Et, acetyl, SH, SMe, carboxyl, aldehyde, amide, amine, nitrile, ester, SO₂NH₃, NH₂, NMe₂, NMeH, and C₂H₂, and “n” may be any integral value from 0 to 4 inclusive.

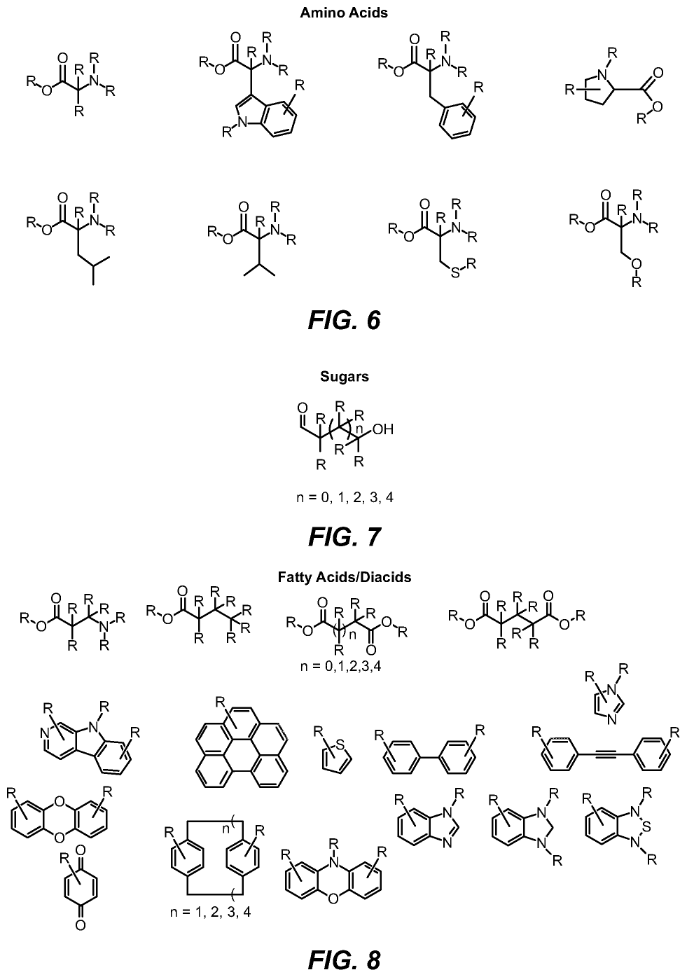

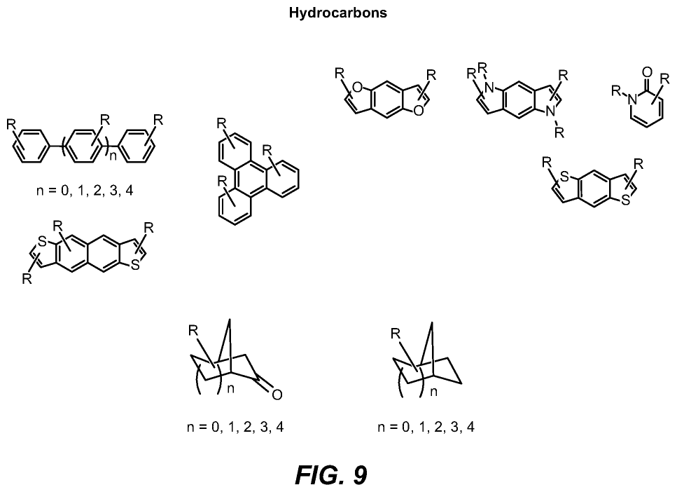

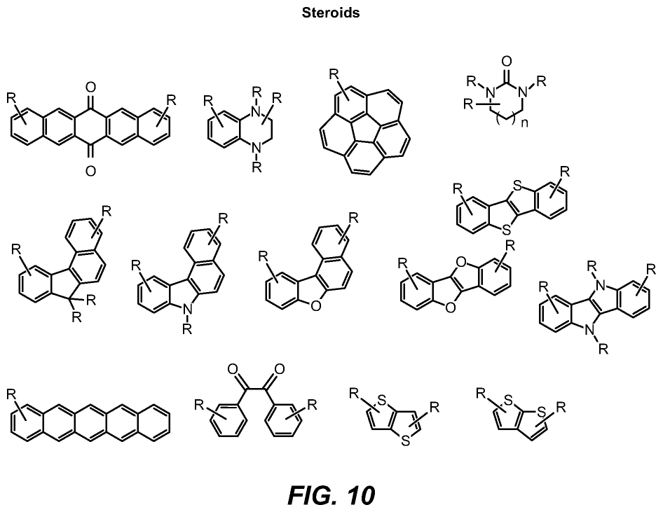

Various example molecules are shown in FIG. 4. Particular example compositions showing the addition of methyl-, hydroxyl-, and fluoro-functional groups to anthracene are shown in FIG. 5. Example amino acids are shown in FIG. 6, example sugars are shown in FIG. 7, and example fatty acids are shown in FIG. 8. As further examples, suitable hydrocarbons are shown in FIG. 9 and suitable steroid compositions are shown in FIG. 10.

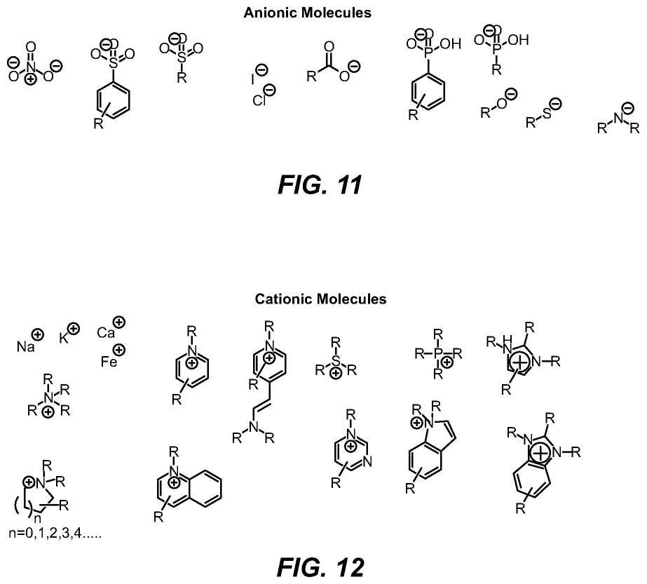

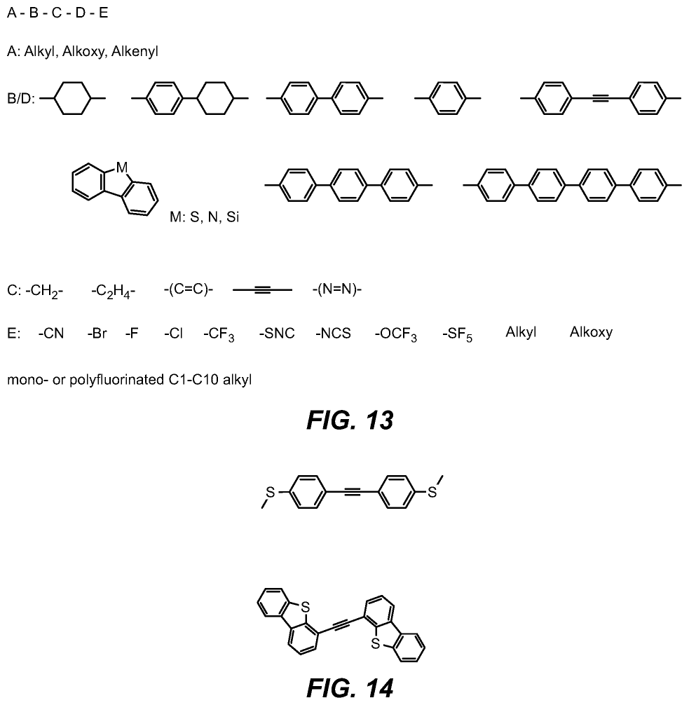

Referring to FIGS. 11 and 12, shown are example anionic molecules and cationic molecules, respectively. Referring to FIG. 13, a modular molecular structure (A-B-C-D-E) is shown, where the individual moieties (A, B, C, D, and E) may be selected in any combination. Exemplary molecules that may be used to form the organic semiconductor layer are shown in FIG. 14. The molecules illustrated in FIG. 14 may be processed to form large crystals at relatively high growth rates while having fewer overall defects and may be used to form an OFET characterized by a high charge mobility.

As disclosed herein, an organic field effect transistor (OFET) includes a channel located between a source and a drain where the channel is formed from a layer of an organic semiconductor. The organic semiconductor may include a single crystal material or a polycrystalline material, for example. A photoalignment layer may be used to template the growth of the organic semiconductor layer and influence the orientation of the crystalline phase, which may impact carrier mobility within the channel.

In certain embodiments, the crystal orientation within the channel may be arranged to provide charge carrier mobility values in excess of approximately 0.01 cm²V⁻¹s⁻¹, i.e., along a direction between the source and drain. According to further embodiments, the photoalignment layer may be configured to template regions within the overlying organic semiconductor having low carrier mobility. Such regions may define isolation regions that block leakage current paths and/or suppress crosstalk between adjacent devices. Thus, in accordance with several embodiments, a layer of photosensitive material may be used to locally (spatially) mediate charge carrier mobility in an over-formed layer of organic semiconductor.

An example method of manufacture may include forming a photoalignment layer, irradiating the photoalignment layer with polarized light, and thereafter forming an organic semiconductor layer over the photoalignment layer.

### EXAMPLE EMBODIMENTS

Example 1: An organic field effect transistor has a channel structure defining an active area located between a source and a drain, where the channel structure includes a photoalignment layer and an organic semiconductor layer disposed directly over the photoalignment layer.

Example 2: The organic field effect transistor of Example 1, where the photoalignment layer includes a material selected from azo-compounds, polyimides, polysilanes, polystyrenes, polyesters, cinnamates, coumarins, chalconyls, tetrahydrophthalimides, and maleimides.

Example 3: The organic field effect transistor of any of Examples 1 and 2, where the photoalignment layer is configured to influence an orientation of molecules within the organic semiconductor layer.

Example 4: The organic field effect transistor of any of Examples 1-3, where the organic semiconductor layer includes a polycrystalline layer or a single crystal layer.

Example 5: The organic field effect transistor of any of Examples 1-4, where the organic semiconductor layer includes a polycyclic aromatic hydrocarbon.

Example 6: The organic field effect transistor of any of Examples 1-5, where the organic semiconductor layer includes a molecule selected from naphthalene, anthracene, tetracene, pentacene, pyrene, polycene, fluoranthene, benzophenone, benzochromene, benzil, benzimidazole, benzene, hexachlorobenzene, nitropyridine-N-oxide, benzene-1, 4-dicarboxylic acid, diphenylacetylene, N-(4-nitrophenyl)-(s)-prolinal, 4,5-dicyanoimidazole, benzodithiophene, cyanopyridine, thienothiophene, stilbene, and azobenzene.

Example 7: The organic field effect transistor of any of Examples 1-6, further including a gate structure located proximate to the channel structure, the gate structure configured to control the conductivity of the channel structure within the active area.

Example 8: The organic field effect transistor of any of Examples 1-7, where the organic semiconductor layer is characterized by a charge carrier mobility of at least approximately 0.01 cm²V⁻¹s⁻¹ within the active area along a direction between the source and the drain.

Example 9: The organic field effect transistor of any of Examples 1-8, where the organic semiconductor layer is characterized by a charge carrier mobility of at least approximately 1 cm²V⁻¹s⁻¹ within the active area along a direction between the source and the drain.

Example 10: The organic field effect transistor of any of Examples 1-9, where the organic semiconductor layer includes an isolation region adjacent to the active area.

Example 11: The organic field effect transistor of any of Examples 1-10, where the organic semiconductor layer includes an amorphous layer within the isolation region.

Example 12: A method includes forming a photoalignment layer, illuminating the photoalignment layer with polarized light to form an oriented photoalignment layer, and forming an organic semiconductor layer directly over the oriented photoalignment layer.

Example 13: The method of Example 12, where the photoalignment layer includes a material selected from azo-compounds, polyimides, polysilanes, polystyrenes, polyesters, cinnamates, coumarins, chalconyls, tetrahydrophthalimides, and maleimides.

Example 14: The method of any of Examples 12 and 13, where the organic semiconductor layer includes a polycyclic aromatic hydrocarbon.

Example 15: The method of any of Examples 12-14, where the organic semiconductor layer includes a molecule selected from naphthalene, anthracene, tetracene, pentacene, pyrene, polycene, fluoranthene, benzophenone, benzochromene, benzil, benzimidazole, benzene, hexachlorobenzene, nitropyridine-N-oxide, benzene-1, 4-dicarboxylic acid, diphenylacetylene, N-(4-nitrophenyl)-(s)-prolinal, 4,5-dicyanoimidazole, benzodithiophene, cyanopyridine, thienothiophene, stilbene, and azobenzene.

Example 16: The method of any of Examples 12-15, further including forming a source adjacent to a first region of the organic semiconductor layer, and forming a drain adjacent to a second region of the organic semiconductor layer, where a charge carrier mobility of the organic semiconductor layer within an active area between the source and the drain is greater than a charge carrier mobility of the organic semiconductor layer within an isolation region adjacent to the active area.

Example 17: The method of Example 16, where the photoalignment layer is illuminated with a first polarized light within the active area and the photoalignment layer is illuminated with a second polarized light within the isolation region.

Example 18: The method of any of Examples 16 and 17, where the organic semiconductor layer is characterized by a charge carrier mobility of at least approximately 0.01 cm²V⁻¹s⁻¹ within the active area along a direction between the source and the drain.

Example 19: An organic field effect transistor includes a photoalignment layer and an organic semiconductor layer disposed directly over the photoalignment layer, where a first region of the organic semiconductor layer is characterized by a first charge carrier mobility and a second region of the organic semiconductor layer is characterized by a second charge carrier mobility.

Example 20: The organic field effect transistor of Example 19, where the first region is located within an active area between a source and a drain and the second region includes an isolation region located adjacent to the active area.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 1500 in FIG. 15) or that visually immerses a user in an artificial reality (e.g., virtual-reality system 1600 in FIG. 16). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 15, augmented-reality system 1500 may include an eyewear device 1502 with a frame 1510 configured to hold a left display device 1515(A) and a right display device 1515(B) in front of a user's eyes. Display devices 1515(A) and 1515(B) may act together or independently to present an image or series of images to a user. While augmented-reality system 1500 includes two displays, embodiments of this disclosure may be implemented in augmented-reality systems with a single NED or more than two NEDs.

In some embodiments, augmented-reality system 1500 may include one or more sensors, such as sensor 1540. Sensor 1540 may generate measurement signals in response to motion of augmented-reality system 1500 and may be located on substantially any portion of frame 1510. Sensor 1540 may represent a position sensor, an inertial measurement unit (IMU), a depth camera assembly, a structured light emitter and/or detector, or any combination thereof. In some embodiments, augmented-reality system 1500 may or may not include sensor 1540 or may include more than one sensor. In embodiments in which sensor 1540 includes an IMU, the IMU may generate calibration data based on measurement signals from sensor 1540. Examples of sensor 1540 may include, without limitation, accelerometers, gyroscopes, magnetometers, other suitable types of sensors that detect motion, sensors used for error correction of the IMU, or some combination thereof.

Augmented-reality system 1500 may also include a microphone array with a plurality of acoustic transducers 1520(A)-1520(J), referred to collectively as acoustic transducers 1520. Acoustic transducers 1520 may be transducers that detect air pressure variations induced by sound waves. Each acoustic transducer 1520 may be configured to detect sound and convert the detected sound into an electronic format (e.g., an analog or digital format). The microphone array in FIG. 15 may include, for example, ten acoustic transducers: 1520(A) and 1520(B), which may be designed to be placed inside a corresponding ear of the user, acoustic transducers 1520(C), 1520(D), 1520(E), 1520(F), 1520(G), and 1520(H), which may be positioned at various locations on frame 1510, and/or acoustic transducers 1520(1) and 1520(J), which may be positioned on a corresponding neckband 1505.

In some embodiments, one or more of acoustic transducers 1520(A)-(F) may be used as output transducers (e.g., speakers). For example, acoustic transducers 1520(A) and/or 1520(B) may be earbuds or any other suitable type of headphone or speaker.

The configuration of acoustic transducers 1520 of the microphone array may vary. While augmented-reality system 1500 is shown in FIG. 15 as having ten acoustic transducers 1520, the number of acoustic transducers 1520 may be greater or less than ten. In some embodiments, using higher numbers of acoustic transducers 1520 may increase the amount of audio information collected and/or the sensitivity and accuracy of the audio information. In contrast, using a lower number of acoustic transducers 1520 may decrease the computing power required by an associated controller 1550 to process the collected audio information. In addition, the position of each acoustic transducer 1520 of the microphone array may vary. For example, the position of an acoustic transducer 1520 may include a defined position on the user, a defined coordinate on frame 1510, an orientation associated with each acoustic transducer 1520, or some combination thereof.

Acoustic transducers 1520(A) and 1520(B) may be positioned on different parts of the user's ear, such as behind the pinna, behind the tragus, and/or within the auricle or fossa. Or, there may be additional acoustic transducers 1520 on or surrounding the ear in addition to acoustic transducers 1520 inside the ear canal. Having an acoustic transducer 1520 positioned next to an ear canal of a user may enable the microphone array to collect information on how sounds arrive at the ear canal. By positioning at least two of acoustic transducers 1520 on either side of a user's head (e.g., as binaural microphones), augmented-reality device 1500 may simulate binaural hearing and capture a 3D stereo sound field around about a user's head. In some embodiments, acoustic transducers 1520(A) and 1520(B) may be connected to augmented-reality system 1500 via a wired connection 1530, and in other embodiments acoustic transducers 1520(A) and 1520(B) may be connected to augmented-reality system 1500 via a wireless connection (e.g., a Bluetooth connection). In still other embodiments, acoustic transducers 1520(A) and 1520(B) may not be used at all in conjunction with augmented-reality system 1500.

Acoustic transducers 1520 on frame 1510 may be positioned along the length of the temples, across the bridge, above or below display devices 1515(A) and 1515(B), or some combination thereof. Acoustic transducers 1520 may be oriented such that the microphone array is able to detect sounds in a wide range of directions surrounding the user wearing the augmented-reality system 1500. In some embodiments, an optimization process may be performed during manufacturing of augmented-reality system 1500 to determine relative positioning of each acoustic transducer 1520 in the microphone array.

In some examples, augmented-reality system 1500 may include or be connected to an external device (e.g., a paired device), such as neckband 1505. Neckband 1505 generally represents any type or form of paired device. Thus, the following discussion of neckband 1505 may also apply to various other paired devices, such as charging cases, smart watches, smart phones, wrist bands, other wearable devices, hand-held controllers, tablet computers, laptop computers, other external compute devices, etc.

As shown, neckband 1505 may be coupled to eyewear device 1502 via one or more connectors. The connectors may be wired or wireless and may include electrical and/or non-electrical (e.g., structural) components. In some cases, eyewear device 1502 and neckband 1505 may operate independently without any wired or wireless connection between them. While FIG. 15 illustrates the components of eyewear device 1502 and neckband 1505 in example locations on eyewear device 1502 and neckband 1505, the components may be located elsewhere and/or distributed differently on eyewear device 1502 and/or neckband 1505. In some embodiments, the components of eyewear device 1502 and neckband 1505 may be located on one or more additional peripheral devices paired with eyewear device 1502, neckband 1505, or some combination thereof.

Pairing external devices, such as neckband 1505, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1500 may be provided by a paired device or shared between a paired device and an eyewear device, thus reducing the weight, heat profile, and form factor of the eyewear device overall while still retaining desired functionality. For example, neckband 1505 may allow components that would otherwise be included on an eyewear device to be included in neckband 1505 since users may tolerate a heavier weight load on their shoulders than they would tolerate on their heads. Neckband 1505 may also have a larger surface area over which to diffuse and disperse heat to the ambient environment. Thus, neckband 1505 may allow for greater battery and computation capacity than might otherwise have been possible on a stand-alone eyewear device. Since weight carried in neckband 1505 may be less invasive to a user than weight carried in eyewear device 1502, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1505 may be communicatively coupled with eyewear device 1502 and/or to other devices. These other devices may provide certain functions (e.g., tracking, localizing, depth mapping, processing, storage, etc.) to augmented-reality system 1500. In the embodiment of FIG. 15, neckband 1505 may include two acoustic transducers (e.g., 1520(1) and 1520(J)) that are part of the microphone array (or potentially form their own microphone subarray). Neckband 1505 may also include a controller 1525 and a power source 1535.

Acoustic transducers 1520(1) and 1520(J) of neckband 1505 may be configured to detect sound and convert the detected sound into an electronic format (analog or digital). In the embodiment of FIG. 15, acoustic transducers 1520(1) and 1520(J) may be positioned on neckband 1505, thereby increasing the distance between the neckband acoustic transducers 1520(1) and 1520(J) and other acoustic transducers 1520 positioned on eyewear device 1502. In some cases, increasing the distance between acoustic transducers 1520 of the microphone array may improve the accuracy of beamforming performed via the microphone array. For example, if a sound is detected by acoustic transducers 1520(C) and 1520(D) and the distance between acoustic transducers 1520(C) and 1520(D) is greater than, e.g., the distance between acoustic transducers 1520(D) and 1520(E), the determined source location of the detected sound may be more accurate than if the sound had been detected by acoustic transducers 1520(D) and 1520(E).

Controller 1525 of neckband 1505 may process information generated by the sensors on neckband 1505 and/or augmented-reality system 1500. For example, controller 1525 may process information from the microphone array that describes sounds detected by the microphone array. For each detected sound, controller 1525 may perform a direction-of-arrival (DOA) estimation to estimate a direction from which the detected sound arrived at the microphone array. As the microphone array detects sounds, controller 1525 may populate an audio data set with the information. In embodiments in which augmented-reality system 1500 includes an inertial measurement unit, controller 1525 may compute all inertial and spatial calculations from the IMU located on eyewear device 1502. A connector may convey information between augmented-reality system 1500 and neckband 1505 and between augmented-reality system 1500 and controller 1525. The information may be in the form of optical data, electrical data, wireless data, or any other transmittable data form. Moving the processing of information generated by augmented-reality system 1500 to neckband 1505 may reduce weight and heat in eyewear device 1502, making it more comfortable to the user.

Power source 1535 in neckband 1505 may provide power to eyewear device 1502 and/or to neckband 1505. Power source 1535 may include, without limitation, lithium ion batteries, lithium-polymer batteries, primary lithium batteries, alkaline batteries, or any other form of power storage. In some cases, power source 1535 may be a wired power source. Including power source 1535 on neckband 1505 instead of on eyewear device 1502 may help better distribute the weight and heat generated by power source 1535.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1600 in FIG. 16, that mostly or completely covers a user's field of view. Virtual-reality system 1600 may include a front rigid body 1602 and a band 1604 shaped to fit around a user's head. Virtual-reality system 1600 may also include output audio transducers 1606(A) and 1606(B). Furthermore, while not shown in FIG. 16, front rigid body 1602 may include one or more electronic elements, including one or more electronic displays, one or more inertial measurement units (IMUS), one or more tracking emitters or detectors, and/or any other suitable device or system for creating an artificial reality experience.

Artificial-reality systems may include a variety of types of visual feedback mechanisms. For example, display devices in augmented-reality system 1500 and/or virtual-reality system 1600 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 1500 and/or virtual-reality system 1600 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 1500 and/or virtual-reality system 1600 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 16, output audio transducers 1606(A) and 1606(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 15, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a photoalignment layer that comprises or includes an azo compound include embodiments where a photoalignment layer consists essentially of an azo compound and embodiments where a photoalignment layer consists of an azo compound.

What is claimed is:

1. An organic field effect transistor comprising:
a channel structure defining an active area located between a source and a drain, the channel structure comprising a photoalignment layer and an organic semiconductor layer disposed directly over the photoalignment layer.

2. The organic field effect transistor of claim 1, wherein the photoalignment layer comprises a material selected from the group consisting of azo-compounds, polyimides, polysilanes, polystyrenes, polyesters, cinnamates, coumarins, chalconyls, tetrahydrophthalimides, and maleimides.

3. The organic field effect transistor of claim 1, wherein the photoalignment layer is configured to influence an orientation of molecules within the organic semiconductor layer.

4. The organic field effect transistor of claim 1, wherein the organic semiconductor layer comprises a polycrystalline layer or a single crystal layer.

5. The organic field effect transistor of claim 1, wherein the organic semiconductor layer comprises a polycyclic aromatic hydrocarbon.

6. The organic field effect transistor of claim 1, wherein the organic semiconductor layer comprises a molecule selected from the group consisting of naphthalene, anthracene, tetracene, pentacene, pyrene, polycene, fluoranthene, benzophenone, benzochromene, benzil, benzimidazole, benzene, hexachlorobenzene, nitropyridine-N-oxide, benzene-1, 4-dicarboxylic acid, diphenylacetylene, N-(4-nitrophenyl)-(s)-prolinal, 4,5-dicyanoimidazole, benzodithiophene, cyanopyridine, thienothiophene, stilbene, and azobenzene.

7. The organic field effect transistor of claim 1, further comprising a gate structure located proximate to the channel structure, the gate structure configured to control the conductivity of the channel structure within the active area.

8. The organic field effect transistor of claim 1, wherein the organic semiconductor layer is characterized by a charge carrier mobility of at least approximately 0.01 cm²V⁻¹s⁻¹ within the active area along a direction between the source and the drain.

9. The organic field effect transistor of claim 1, wherein the organic semiconductor layer is characterized by a charge carrier mobility of at least approximately 1 cm²V⁻¹s⁻¹ within the active area along a direction between the source and the drain.

10. The organic field effect transistor of claim 1, wherein the organic semiconductor layer comprises an isolation region adjacent to the active area.

11. The organic field effect transistor of claim 1, wherein the organic semiconductor layer comprises an amorphous layer within the isolation region.

12. A method comprising:
forming a photoalignment layer;
illuminating the photoalignment layer with polarized light to form an oriented photoalignment layer; and
forming an organic semiconductor layer directly over the oriented photoalignment layer.

13. The method of claim 12, wherein the photoalignment layer comprises a material selected from the group consisting of azo-compounds, polyimides, polysilanes, polystyrenes, polyesters, cinnamates, coumarins, chalconyls, tetrahydrophthalimides, and maleimides.

14. The method of claim 12, wherein the organic semiconductor layer comprises a polycyclic aromatic hydrocarbon.

15. The method of claim 12, wherein the organic semiconductor layer comprises a molecule selected from the group consisting of naphthalene, anthracene, tetracene, pentacene, pyrene, polycene, fluoranthene, benzophenone, benzochromene, benzil, benzimidazole, benzene, hexachlorobenzene, nitropyridine-N-oxide, benzene-1, 4-dicarboxylic acid, diphenylacetylene, N-(4-nitrophenyl)-(s)-prolinal, 4,5-dicyanoimidazole, benzodithiophene, cyanopyridine, thienothiophene, stilbene, and azobenzene.

16. The method of claim 12, further comprising:
forming a source adjacent to a first region of the organic semiconductor layer; and
forming a drain adjacent to a second region of the organic semiconductor layer, wherein a charge carrier mobility of the organic semiconductor layer within an active area between the source and the drain is greater than a charge carrier mobility of the organic semiconductor layer within an isolation region adjacent to the active area.

17. The method of claim 16, wherein the photoalignment layer is illuminated with a first polarized light within the active area and the photoalignment layer is illuminated with a second polarized light within the isolation region.

18. The method of claim 16, wherein the organic semiconductor layer is characterized by a charge carrier mobility of at least approximately 0.01 cm²V⁻¹s⁻¹ within the active area along a direction between the source and the drain.

19. An organic field effect transistor comprising a photoalignment layer and an organic semiconductor layer disposed directly over the photoalignment layer, wherein a first region of the organic semiconductor layer is characterized by a first charge carrier mobility and a second region of the organic semiconductor layer is characterized by a second charge carrier mobility.

20. The organic field effect transistor of claim 19, wherein the first region is located within an active area between a source and a drain and the second region comprises an isolation region located adjacent to the active area.
